(19) United States
(12) Patent Application Publication
(10) Pub. No.: US 2005/0017371 A1
(43) Pub. Date: Jan. 27, 2005

(54) Electronic assembly having a die with rounded corner edge portions and a method of fabricating the same

(76) Inventors: Zhiyong Wang, Chandler, AZ (US); Song-Hua Shi, Phoenix, AZ (US); Lars D. Skoglund, Chandler, AZ (US); Rajen C. Dias, Phoenix, AZ (US)

Correspondence Address: Stephen M. De Klerk;BLAKELY, SOKOLOFF, TAYLOR & ZAFMAN LLP, Seventh Floor, 12400 Wilshire Boulevard, Los Angeles, CA, 90025-1026, US

(21) Appl. No.: 10/625,109

(22) Filed: Jul. 22, 2003

(51) Int. Cl. H01L 29/40

(52) U.S. Cl. 257/778

(57) ABSTRACT

The invention provides an electronic assembly comprising a carrier substrate, a die, and a solidified underfill material. The carrier substrate has an upper plane. The die has a die substrate and an integrated circuit formed on one side of the die substrate. The die has a lower major surface over the upper plane, an upper major surface, and a plurality of side edge surfaces from the upper major surface to the lower major surface. A corner edge portion where extensions of two of the side edge surfaces meet has been removed. The solidified underfill material is located between and contacts both the upper plane of the carrier substrate and the lower surface of the die.

### BACKGROUND OF THE INVENTION

1). Field of the Invention

This invention relates generally to an electronic assembly of the kind having a die with an integrated circuit formed thereon, and more specifically to prevention of cracking of the electronic assembly due to differences in coefficients of thermal expansion of the die, an underfill material below the die, and a package substrate.

2). Discussion of Related Art

Integrated circuits are formed in rows and columns on semiconductor wafers, which are subsequently “singulated” or “diced” by directing a blade of a saw through scribe streets in x- and y-directions between the integrated circuits. Resulting dies have conductive interconnection members that can be placed on contact terminals of a package substrate, and be soldered to the contact terminals.

A package substrate typically has a coefficient of thermal expansion (CTE) which is higher than that of the die, which creates stresses on the interconnection members when the electronic assembly heats up and cools down. An epoxy underfill material is often applied to the package substrate, flows into a space between the package substrate and the die under capillary action, and is subsequently cured at a high temperature. The stresses on the interconnection members are redistributed to the solidified underfill material.

The underfill material typically has a CTE which is even higher than that of the substrate, which creates stresses on certain areas of the die when the assembly cools down after the underfill material is cured. These stresses are particularly high at corner edge portions of the die where side edge surfaces thereof meet, and may cause cracking in the die, the underfill material, or in the package substrate at or near the corner edge portions of the die.

### BRIEF DESCRIPTION OF THE DRAWINGS

The invention is described by way of example with reference to the accompanying drawings, wherein:

FIG. 1 is a plan view of a semiconductor wafer having a plurality of integrated circuits formed thereon;

FIG. 2 is a cross-sectional side view of a portion of the semiconductor wafer which is mounted on a support layer;

FIG. 3 is a plan view of the wafer after the wafer has been singulated into individual dies;

FIG. 4 is a view similar to FIG. 2, illustrating a blade of a saw as it travels through the wafer;

FIG. 5 is a view similar to FIG. 4, further illustrating a laser that is used to remove portions of the dies;

FIG. 6 is an enlarged plan view illustrating a region of one of the dies where a corner edge portion thereof is removed;

FIG. 7 is a top plan view of an electronic assembly that includes one of the dies;

FIG. 8 is a cross-sectional side view of the electronic assembly on 8-8 in FIG. 7; and

FIG. 9 is a cross-sectional view on 9-9 in FIG. 7.

### DETAILED DESCRIPTION OF THE INVENTION

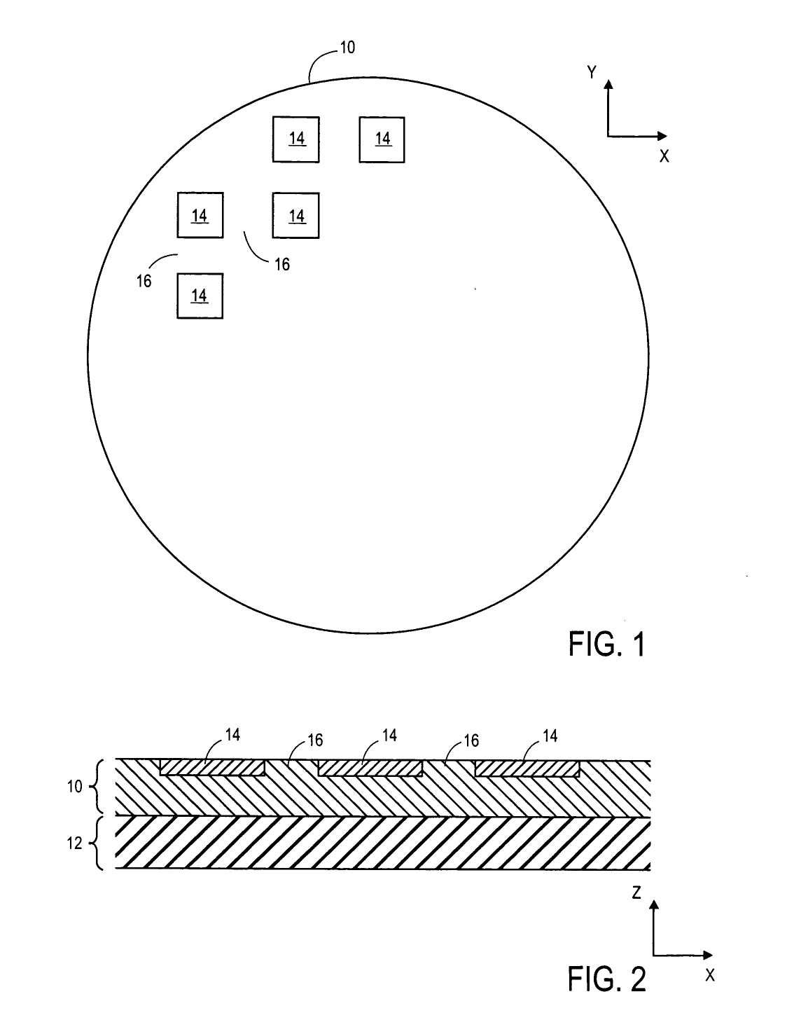

FIGS. 1 and 2 of the accompanying drawings illustrate a semiconductor wafer 10 which has been attached to a supporting layer 12, typically made of Mylar®, for purposes of sawing the wafer 10. The wafer 10, as will be commonly understood, has a plurality of identical circuits 14 that are replicated in rows and columns across a circular area of the wafer. Scribe streets 16 are defined in x- and y-directions between the circuits 14. A respective rectangular guard ring (not shown) surrounds each respective circuit 14.

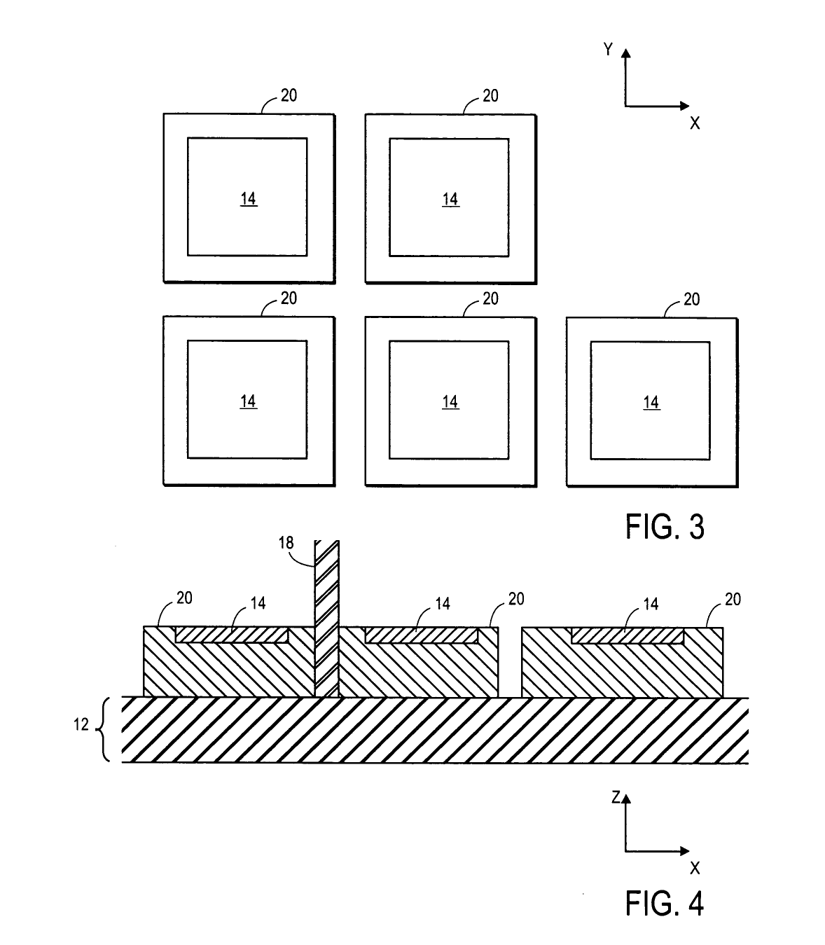

As illustrated in FIGS. 3 and 4, a blade 18 of a saw is directed through the wafer (10 in FIG. 1) so that the wafer is singulated into individual dies 20. The blade 18 is not intended to cut through the supporting layer 12, but may cut it partially. The dies 20 are attached to the supporting layer 12, and the supporting layer 12 maintains the dies 20 in their original position of FIG. 1. The blade 18 is directed through the scribe streets (16 in FIG. 1) and between the guard rings so that the circuits 14 are protected by the guard rings. Each die 20 includes a respective one of the circuits 14.

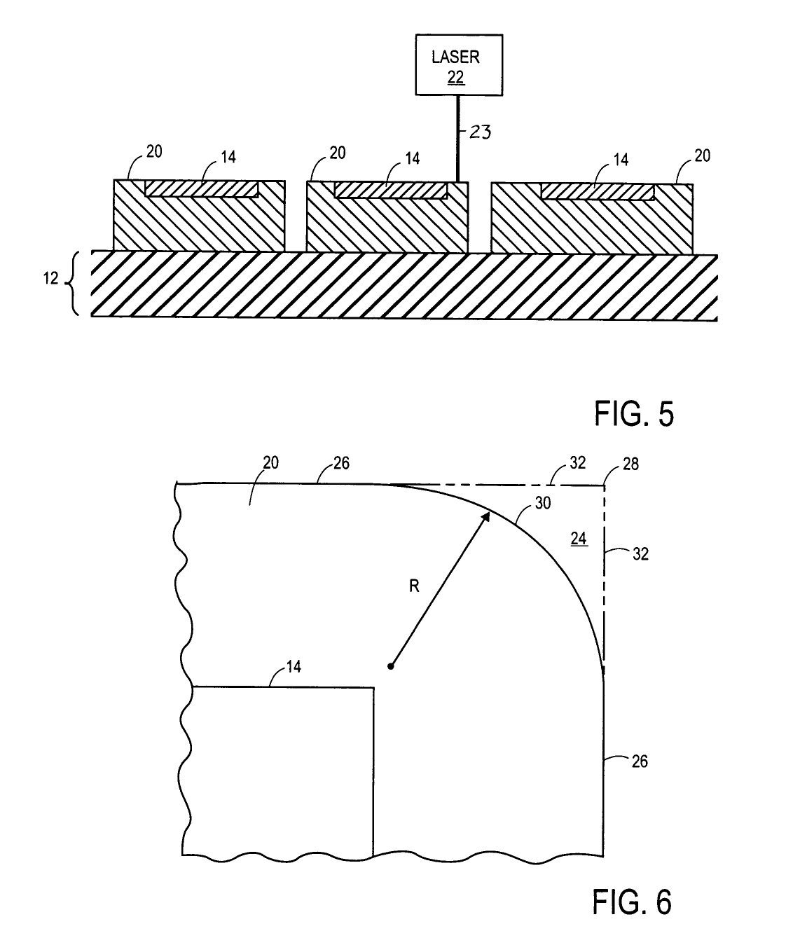

FIG. 5 illustrates further processing of the dies 20, wherein a laser 22 is used to remove portions of the dies 20. The laser 22 is preferably an Excimer laser, because an Excimer laser beam does not transfer heat to an object that is being ablated. The laser 22 is positioned above the dies 20, and a laser beam 23 is directed by the laser 22 onto one of the dies 20. Laser is preferred over grinding and milling because of the possibility to produce higher volumes. Laser is also preferred over etching because of tighter control over dimensional tolerances.

FIG. 6 illustrates a portion of one of the dies 20 after a corner edge portion 24 thereof has been removed with the laser 22 in FIG. 5. Before removal of the corner edge portion 24, the die 20 has two side edge surfaces 26 that meet at right angles to one another at a corner edge 28. After removal of the corner edge portion 28, the die 20 has a rounded surface 30 that joins remaining portions of the side edge surfaces 26. The corner edge portion 24 is thus bound by the rounded surface 30 and extensions 32 of the side edge surfaces 26.

The rounded surface 30 may have a radius (R) of between 50 μm and 1000 μm. The corner edge portion 24 accordingly has an area of between 537 μm² and 860000 μm². The purpose for providing these ranges is merely to establish that the intent is to differentiate over the tiny radii found on sharp, even knifelike edges.

Referring to FIG. 3, the process of removing a corner edge portion from one of the dies 20 is repeated on all four corners of each one of the rectangular dies 20. It can thus be seen that removal of the corner edge portions is automated by removing the corner edge portions directly after the dies 20 are singulated, but before the dies 20 are removed from the supporting layer 12.

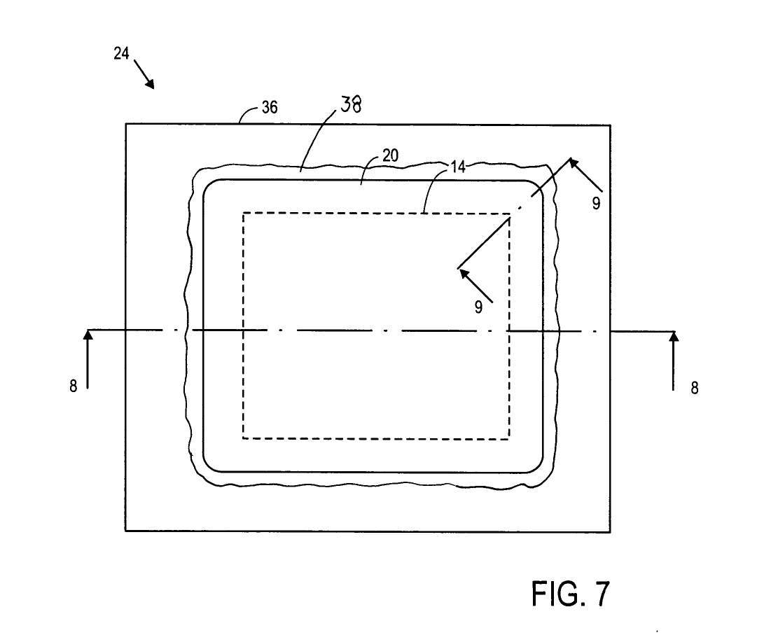

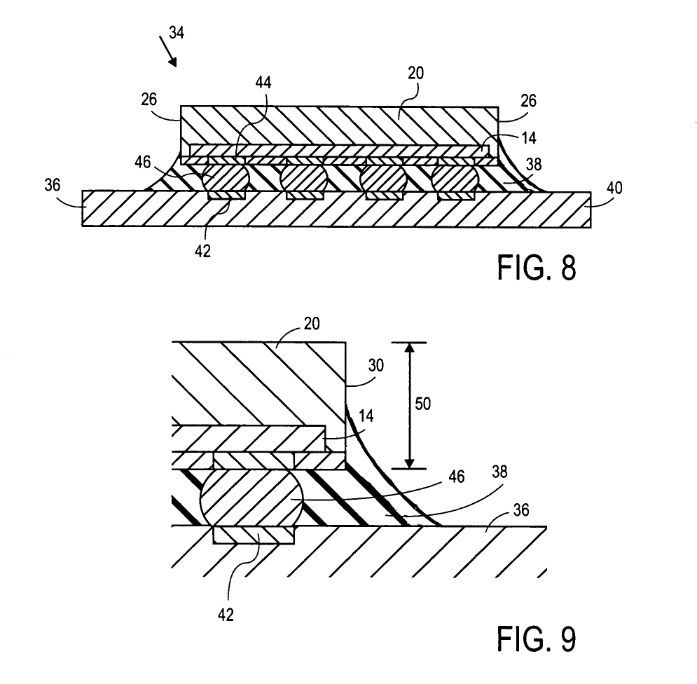

FIGS. 7 and 8 illustrate an electronic assembly 34 that includes a package substrate 36, one of the dies 20, and an underfill material 38. The package substrate 36 includes a carrier substrate 40 and a plurality of contact terminals 42 formed at an upper surface of the carrier substrate 40. The die 20 also has a plurality of contact pads 44 and a plurality of conductive solder ball interconnection members 46, each attached to a respective one of the contact pads 44.

The die 20 is placed on the package substrate 36 so that each one of the interconnection members 46 is on a respective one of the contact terminals 42. The contact terminals 42 are in rows and columns forming an array, and the interconnection members 46 have a pattern that matches the pattern of the contact terminals 42. The entire assembly, excluding the underfill material 38, is then heated in a reflow oven so that the interconnection members 46 melt, and is subsequently allowed to cool. The interconnection members 46 are so soldered and secured to the contact terminals 42.

The underfill material 38 is an epoxy that is applied in liquid form on the package substrate 36 around the die 20. Capillary forces draw the liquid underfill material 38 into a space between an upper surface of the carrier substrate 40 and a lower surface of the die 20 between the interconnection members 46. The entire volume between the die 20 and the carrier substrate 40 is substantially filled with the liquid underfill material 38, and some of the underfill material 38 also forms on side edge surfaces 26 of the die 20.

As illustrated in FIG. 9, the rounded surface 30 has formed through an entire thickness 50 of the die 20. The die 20 typically has a thickness of about 740 μm, and the rounded surface 30 thus also has a thickness of 740 μm. The underfill material 38 is also formed on a lower portion of the rounded surface 30.

The entire assembly illustrated in FIGS. 7, 8, and 9 is then located in an oven and heated to a temperature sufficient to allow the underfill material 38 to cure. Curing solidifies the underfill material 38. The assembly 34 is then allowed to cool. The underfill material 38 has a CTE of between 16 and 50 ppm/° C., the die 20 has a CTE of approximately 4 ppm/° C., and the package substrate 36 has a CTE of approximately 20 ppm/° C. The different coefficients of thermal expansion creates stresses on the die 20 when the electronic assembly 34 is allowed to cool after curing of the underfill material 38. These stresses are particularly high at sharp edges. By removing the corner edge portion 24, these stresses are reduced. Rounded corners, as opposed to, for example, faceted corners, are particularly effective for reducing stresses. Dome-shaped corners may be even more effective to reduce stresses than cylindrically rounded corners, but may be more difficult to manufacture. By reducing the stresses, cracking of any part of the electronic assembly is avoided in a region where side edge surfaces thereof meet.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

1. An electronic assembly, comprising:
a carrier substrate having an upper plane;
a die having a die substrate and an integrated circuit formed on one side of the die substrate, the die having a lower major surface over the upper plane, an upper major surface, and a plurality of side edge surfaces from the upper major surface to the lower major surface, a corner edge portion where extensions of two of the side edge surfaces meet, having been removed; and
a solidified underfill material between and contacting both the upper plane of the carrier substrate and the lower surface of the die.

2. The electronic assembly of claim 1, wherein the corner edge portion has an area of between 537 μm² and 860000 μm².

3. The electronic assembly of claim 1, wherein the die is rounded at the corner edge portion.

4. The electronic assembly of claim 3, wherein the die has a radius of between 50 μm and 1000 μm at the corner edge portion.

5. The electronic assembly of claim 3, wherein an entire thickness of the die from the upper to the lower major surface is rounded.

6. The electronic assembly of claim 1, wherein the underfill material has a different CTE than the substrate.

7. The electronic assembly of claim 1, further comprising:
a plurality of conductive interconnection members between and electrically connecting the carrier substrate to the die, the underfill material being disposed between the conductive interconnection members.

8. An electronic component, comprising:
a die having a die substrate and an integrated circuit formed on the die substrate, the die having upper and lower major surfaces and a plurality of side edge surfaces from the upper to the lower major surface, a corner edge portion where extensions of two of the side edge surfaces meet, having been removed.

9. The electronic component of claim 8, wherein the corner edge portion has an area of between 537 μm² and 860000 μm².

10. The electronic component of claim 8, wherein the die is rounded at the corner edge portion.

11. The electronic component of claim 10, wherein the die has a radius of between 50 μm and 1000 μm at the corner edge portion.

12. The electronic component of claim 10, wherein an entire thickness of the die from the upper to the lower major surface is rounded.

13. The electronic component of claim 8, further comprising:
a plurality of conductive interconnection members on a side of the die of the integrated circuit.

14. The electronic component of claim 13, wherein the conductive interconnection members are solder balls.

15. A method of making microelectronic dies, comprising:
singulating a wafer substrate on which a plurality of integrated circuits are formed into a plurality of dies, each die including a respective one of the integrated circuits, and each die having opposing major surfaces and a plurality of side edge surfaces connecting the major surfaces; and
removing a corner edge portion of each die where two side edge surfaces of the respective die meet.

16. The method of claim 15, wherein the portions are removed after the dies are singulated.

17. The method of claim 15, wherein the portions are removed with an Excimer laser beam.

18. A method of constructing an electronic assembly, comprising:
mounting a die having a die substrate and an integrated circuit formed on the die substrate over a carrier substrate with an underfill material between and contacting both one major surface of the die and a plane of the carrier substrate;
heating the underfill material to cure the underfill material; and
allowing the underfill material to cool, the die having side edge surfaces from the one major surface to an opposing major surface thereof, a corner portion where two of the side edge surfaces meet, having been removed to reduce stresses that may crack the die due to differential coefficients of thermal expansion of the die and the underfill material.

19. The method of claim 18, further comprising:
singulating a wafer substrate on which a plurality of integrated circuits are formed into a plurality of dies, each including a respective one of the integrated circuits, and each die having opposing major surfaces and a plurality of side edge surfaces connecting the major surfaces; and
removing a corner edge portion of each die where two side edge surfaces of the respective die meet, one of the dies being the die that is mounted.

20. The method of claim 19, wherein the portions are removed with an Excimer laser beam.
